(19) United States
(12) Patent Application Publication
(10) Pub. No.: US 2010/0216667 A1
(43) Pub. Date: Aug. 26, 2010

(54) METHOD FOR DETERMINING COMPATIBILITY OF AN ACTIVE PHARMACEUTICAL INGREDIENT WITH MATERIALS

(76) Inventors: Brian K. Meyer, New Britain, PA (US); Leonardo R. Allain, Lansdale, PA (US); David Geer, Eagleville, PA (US); Rajiv Mahajan, Lansdale, PA (US); David R. Walker, Lansdale, PA (US); Marc J. Kirchmeier, Harleysville, PA (US)

Correspondence Address: MERCK, P O BOX 2000, RAHWAY, NJ, 07065-0907, US

(21) Appl. No.: 12/640,481

(22) Filed: Dec. 17, 2009

Related U.S. Application Data
(60) Provisional application No. 61/209,968, filed on Mar. 13, 2009.
(60) Provisional application No. 61/201,968, filed on Dec. 17, 2008.

(51) Int. Cl. C40B 30/10; G01N 27/26; G01N 30/02; H01J 49/26; G01R 33/44; G01N 21/47

(52) U.S. Cl. 506/12; 204/452; 204/469; 73/61.52; 250/282; 324/307; 356/300

(57) ABSTRACT

Disclosed is a system or matrix approach for determining compatibility of a pharmaceutically active substance, such as small molecule drug candidate, therapeutic proteins, peptides, vaccines or RNAi, with materials used in the research and development of pharmaceuticals, including plastics, polymers, resins, rubbers, elastomers, glass and steel.

### CROSS-REFERENCE TO RELATED APPLICATIONS

This application claims priority under 35 U.S.C. §1119(e) of U.S. provisional application Ser. No. 61/209,968, filed Dec. 17, 2008.

### FIELD OF THE INVENTION

The invention is directed to a system or matrix approach for determining compatibility of a pharmaceutically active substance with materials used in the research and development of pharmaceuticals. In particular, the invention is directed to a high-throughput system for determining the compatibility of a pharmaceutically active substance with a plurality of materials.

### BACKGROUND OF THE INVENTION

The research and development of pharmaceuticals requires extensive use of materials for storage, dosing, and testing of pharmaceutically active substances. Various thermoplastic, elastomeric, metal and composite materials are used in product packaging, dosing and storage during drug development and commercial use. Materials used in laboratory studies, safety assessment, drug substance bulk processing, formulation, filling, administration, and drug product manufacture and storage are potential product contact surfaces, which could interact for significant periods of time with pharmaceutically active substances.

A wide variety of materials are used as potential product contact surfaces, in bottles, tubing, syringes, intravenous bags, coatings, bulk storage containers and other products. Suitable plastics materials used in such products include polyolefins (including ethylene/propylene or ethylene vinyl acetate copolymers, polyethylenes, polypropylenes, polystyrenes and polyvinyl chloride), polyesters (including polyethylene terephthalate) and polycarbonates. Elastomeric or rubber materials, such as chlorobutyls, bromobutyls and styrene-butadiene blends, are widely used in stoppers and caps. Various glass materials are used in vials, syringes and product storage. Stainless steels are used in tanks and other storage products, and as components of plastic and rubber products.

There is a need for researchers to obtain information as early as possible during drug development about potential compatibility problems that pharmaceutically active substances may have upon interaction or contact with potential product contact surface materials. Potential compatibility problems (such as any harmful or unsuitable interactions) include loss of the pharmaceutically active substance via adsorption/absorption, degradation of the product or material, product contamination, or any other undesirable chemical or physical interactions of the pharmaceutically active substance with the material. Ideally, researchers would discover any incompatibility with materials prior to commercial use, and even before clinical testing.

Typically, in order to determine compatibility problems, materials such as tanks, syringes, catheters, infusion lines, and IV bags are tested individually to assess compatibility with the pharmaceutically active substance under development. These procedures often involve use of actual-scale materials, and relatively large volumes of the pharmaceutically active substance.

Inadequate materials compatibility screening has contributed to materials interaction problems that were not discovered until commercialization. For example, several years ago an increase in pure red cell aplasia (PRCA) was observed in patients being treated with EPREX. PRCA is a condition that results from antibodies being raised against the active ingredient of EPREX, which is erythropoietin. An investigation concluded that leachates from uncoated stoppers and the presence of Polysorbate-80 in pre-filled EPREX syringes resulted in an increased incidence of PRCA. Sharma, B., et al, 2004, “Technical Investigations into the Cause of the Increased Incidence of Antibody-Mediated Pure Red Cell Aplasia Associated with EPREX,” European Association of Hospital Pharmacists. 5: 86-91; Villalobos, A. P., et al, 2005, “Interaction of Polysorbate 80 with Erythropoietin: A Case Study in Protein-Surfactant Interactions,” Pharm. Res. 22 (7): 1186-1194. Replacement of the uncoated stoppers with coated stoppers reduced PRCA cases to baseline.

In another example, the potency of a dental anesthetic was affected by zinc that leached from a rubber plunger in pre-filled syringes. PDA Course Handbook: Assessing Packaging and Processing Extractables/Leachables, 7-8 May 2007 (Indianapolis, Ind.).

Hence, there is a need in the pharmaceutical industry for a material compatibility screening procedure to provide information about interactions between a pharmaceutically active substance and materials during early drug development, to prevent issues in later phases of development or in the clinic. The use of a matrix approach to screen compatibility of materials (as opposed to the individual testing paradigm that is commonly used at present) would greatly reduce the amount of materials and resources required for such studies. A desirable matrix screening system could assess the compatibility of various categories of pharmaceutically active substances, including but not limited to small molecules, RNAi moieties, peptides, proteins and vaccines, with a wide variety of materials.

### SUMMARY OF THE INVENTION

The invention is directed to a method for screening compatibility of a pharmaceutically active substance with a plurality of materials, comprising the steps of:

(a) providing at least one pharmaceutically active substance and/or at least one pharmaceutically acceptable carrier;

(b) providing a plurality of materials, wherein each of the materials is present in a discrete non-reactive vessel;

(c) incubating the pharmaceutically active substance and/or the optional pharmaceutically acceptable carrier with each of the plurality of materials in the non-reactive vessels;

(d) measuring integrity of the pharmaceutically active substance or the material in each of the non-reactive vessels to obtain a first set of integrity readouts; and

(e) comparing the first set of integrity readouts with one or more control integrity readouts.

### BRIEF DESCRIPTION OF THE DRAWINGS

FIG. 1A is a chromatogram with ultraviolet detection of a therapeutic protein active ingredient as a control, as incubated with polycarbonate material, and as incubated with ULTEM 1000 plastic material, and FIG. 1B is a chromatogram with ultraviolet detection of the same therapeutic protein active ingredient as a control, as incubated with PEEK material, and as incubated with an ethylene propylene material; and

FIG. 2 is a chromatogram with ultraviolet detection of a small molecule active ingredient as a control, as incubated with low density polyethylene, and as incubated with a commercially available filter material.

### DETAILED DESCRIPTION OF THE INVENTION

In one embodiment, which may be referred to the degradation assay, the invention is directed to a method for screening compatibility of a pharmaceutically active substance with a plurality of materials, comprising the steps of:

(a) providing at least one pharmaceutically active substance and optionally at least one pharmaceutically acceptable carrier;

(b) providing a plurality of materials, wherein each of the materials is present in a discrete non-reactive vessel;

(c) incubating the pharmaceutically active substance and the optional pharmaceutically acceptable carrier with each of the plurality of materials in the non-reactive vessels;

(d) measuring integrity of the pharmaceutically active substance in each of the non-reactive vessels to obtain a first set of integrity readouts;

(e) comparing the first set of integrity readouts with one or more control integrity readouts.

The control integrity readout may be generated by the steps of:

(f) incubating the pharmaceutically active substance and optionally the pharmaceutically acceptable carrier in a control non-reactive vessel; and

(g) measuring the integrity of the pharmaceutically active substance in the control non-reactive vessel to obtain a control integrity readout.

In particular embodiments, the integrity is determined by an analytical method selected from the group consisting of high performance liquid chromatography (HPLC), including size-exclusion high performance liquid chromatography (S-E HPLC) and reverse-phase high performance liquid chromatography (R-P HPLC); cation exchange liquid chromatography (CEX-HPLS); capillary isoelectric focusing (cIEF); sodium dodecyl sulfate polyacrylamide gel electrophoresis (SDS-PAGE); nuclear magnetic resonance (NMR); mass spectrometric techniques; spectroscopy, including ultra-violet spectroscopy, visible light spectroscopy, near-infra red spectroscopy, fourier transform infrared spectroscopy, Raman spectroscopy, fluorescence spectroscopy, inductively coupled plasma mass spectroscopy (ICP-MS), and Plasmon resonance techniques; dynamic light scattering and static light scattering.

Typically, the pharmaceutically active substance is selected from the group consisting of proteins, vaccines, RNAi, peptides, and small molecules.

The incubation of step (c) may be conducted at any predetermined temperature. In one embodiment, suitable incubation temperatures are between 15 and 50° C., preferably between 20 and 40° C. Exemplary incubation temperatures are 15° C., 20° C., 25° C., 30° C., 35° C., 37° C. and 40° C.

In another embodiment, suitable incubation temperatures are below freezing, for example from −75° C. to −15° C. Exemplary incubation temperatures in this embodiment are −75° C., −70° C., −65° C., −60° C., −55° C., −50° C., −45° C., −40° C., −35° C., −30° C., −25° C., −20° C. and −15° C.

The incubation of step (c) may be conducted for any predetermined period of time, from periods of hours to days, weeks or months. Suitable incubation times are between 24 hours and six weeks. Exemplary incubation times are 24 hours, 36 hours, 48 hours, 60 hours, 72 hours, one week, two weeks, three weeks, four weeks, five weeks and six weeks.

The incubation of step (f) may be conducted at the same temperature as the incubation of step (c). In certain embodiments, it is desirable to obtain control integrity readouts at different incubation temperatures than the step (c) incubation. In this embodiment, typically, the incubation of step (f) is conducted at a temperature lower than that of step (c). Often, and in particular when the step (c) incubation temperatures are between 15 and 50° C., the incubation of step (f) is conducted at a temperature between 2 and 8° C. Exemplary lower incubation temperatures are 2° C., 3° C., 4° C., 5° C., 6° C., 7° C. and 8° C.

When the incubation of step (c) is conducted at a freezing temperature, then the incubation of step (f) is typically at a higher temperature, from −5° C. to 0° C. (e.g., −1° C.), or a higher “thaw” temperature, between 15 and 50° C. (e.g., 20° C. or 25° C.).

Typically, the materials are selected from the group consisting of polymers, elastomers, glasses and metals.

In particular embodiments, the non-reactive vessels are small glass cylinders (e.g., 1 mL).

In particular embodiments, the non-reactive vessels are 3 ml glass vials or tubes.

In particular embodiments, samples of the plurality of materials in the discrete non-reactive vessels have a surface area to volume ratio of from 1.0 cm²/mL to 10.0 cm²/mL (i.e., from 1.0 cm² material/mL pharmaceutically active substance and carrier, to 10.0 cm²/mL pharmaceutically active substance and carrier).

In particular embodiments, the surface area to volume ratio of the plurality of materials to the pharmaceutically active substance and any pharmaceutical carrier is from 3.0 cm²/mL to 7.0 cm²/mL (i.e., from 3.0 cm² material/mL pharmaceutically active substance and carrier, to 7.0 cm²/mL pharmaceutically active substance and carrier).

In one embodiment, the non-reactive vessels are present in a tray. The tray may be, for example, a 90-well tray adapted for using 3 mL vials, or a 96-well tray containing small glass cylinders. In certain embodiments, the tray (particularly the 96-well tray) may be deployed in a robotic assay system, in which the pharmaceutically active substance and materials are robotically dispensed to the tray, and the assay steps are conducted robotically. In particular embodiments, the method for screening is a high-throughput robotic assay method.

In another embodiment, the tray may be an HPLC (“high performance liquid chromatography”) sample tray, which is engineered for HPLC instruments. Typical HPLC sample trays have 100 slots for vials. An example of a commercially available HPLC sample tray is found in the Agilent 1100 HPLC system.

In another embodiment, which may be referred to as the leachables assay, the invention is directed to a method for screening compatibility of a pharmaceutically active substance or a pharmaceutically acceptable carrier with a plurality of materials, comprising the steps of:

(a) providing at least one pharmaceutically active substance or at least one pharmaceutically acceptable carrier;

(b) providing a plurality of materials, wherein each of the materials is present in a discrete non-reactive vessel;

(c) incubating the pharmaceutically active substance or pharmaceutically acceptable carrier with each of the plurality of materials in the non-reactive vessels;

(d) measuring integrity of the materials in each of the non-reactive vessels to obtain a first set of integrity readouts; and

(e) comparing the first set of integrity readouts with one or more control integrity readouts.

The control integrity readout of the leachables assay may be generated by the steps of:

(f) incubating the pharmaceutically active substance or pharmaceutically acceptable carrier in a control non-reactive vessel; and

(g) measuring the integrity of the pharmaceutically active substance or pharmaceutically acceptable carrier in the control non-reactive vessel to obtain a control integrity readout.

In particular embodiments of the leachables assay, the pharmaceutically active substance or pharmaceutically acceptable carrier is a liquid pharmaceutical formulation, comprising a pharmaceutically active substance and at least one pharmaceutically acceptable carrier.

In particular embodiments of the leachables assay, the integrity of the material is determined by an analytical method selected from the group consisting of high performance liquid chromatography (HPLC), including reverse-phase high performance liquid chromatography (R-P HPLC); and mass spectroscopy, including gas chromatography-mass spectroscopy (CG-MS), liquid chromatography-mass spectroscopy (LC-MS) and inductively coupled plasma mass spectroscopy (ICP-MS).

In some embodiments of the leachables assay, the materials are incubated with one or more pharmaceutically acceptable carriers, but without a pharmaceutically active ingredient (i.e., with a placebo).

The incubation of step (c) for the leachables assay may be conducted at any predetermined temperature. In particular, the leachables assay can be conducted at the same ranges and exemplary temperatures identified for the degradation assay.

The incubation of step (c) for the leachables assay may be conducted for any predetermined period of time, from periods of hours to days, weeks or months. In particular, the leachables assay can be conducted at the same ranges and exemplary times identified for the degradation assay.

In the leachables assay, the incubation of step (f) may be conducted at the same temperature as the incubation of step (c). In certain embodiments, it is desirable to obtain control integrity readouts at different incubation temperatures than the step (c) incubation. In this embodiment, typically, the incubation of step (f) is conducted at a temperature lower than that of step (c). Often, and in particular when the step (c) incubation temperatures are between 15 and 50° C., the incubation of step (f) is conducted at a temperature between 2 and 8° C.

The leachables assay may be conducted with the same types of materials, vessels and trays as the degradation assay.

The leachables assay may be conducted with the same surface area to volume ratios (e.g., from 1.0 cm² material/mL pharmaceutically active substance and carrier, to 10.0 cm²/mL pharmaceutically active substance and carrier) as the degradation assay.

As used herein, the term “pharmaceutically active substance” means any molecule that is believed to be useful for the treatment or prevention of disease in mammals. The invention is not intended to be limited to use with particular types of groups of pharmaceutically active substances, and includes any substance that is under study or consideration as a drug candidate for the treatment or prevention of disease in mammals. Exemplary “pharmaceutically active substances” for use in the invention include, but are not limited to, small molecule compounds (compounds having a molecular weight of less than 1000 Daltons, and typically between 300 and 700 Daltons), peptides, proteins, antibodies, molecular complexes, lipid particles, nanoparticles or RNAi. A “pharmaceutically active substance” as used herein may also include the active ingredients of any marketed drugs.

As used herein, the term “pharmaceutically acceptable carrier” means carriers, excipients, buffers or fillers that are commonly used in pharmaceutical formulations or dosage forms. Suitable carriers that may be used in the invention include carriers typically used in oral dosage forms, such as additives to make tablets, powders, granules or capsules. Common carriers are conventional solvents and additives, such as water, saline, ethanol, dextrose, glycerol, lactose, mannitol, corn starch or potato starch; binders, such as crystalline cellulose, cellulose derivatives, acacia, corn starch or gelatins; disintegrators, such as corn starch, potato starch or sodium carboxymethylcellulose; lubricants, such as talc or magnesium stearate; diluents, buffering agents, moistening agents, preservatives and flavoring agents. Pharmaceutically acceptable carriers or excipients are described in a variety of publications, including, for example, A. Gennaro (1995) “Remington: The Science and Practice of Pharmacy”, 19th edition, Lippincott, Williams, & Wilkins.

Carriers used in injectable dosage forms that may be used in the invention include aqueous or nonaqueous solvents, such as vegetable or other similar oils, synthetic aliphatic acid glycerides, esters of higher aliphatic acids or propylene glycol, and conventional additives such as solubilizers, isotonic agents, suspending agents, emulsifying agents, stabilizers and preservatives.

Carriers used in aerosol formulations that may be used in the invention include propellants such as dichlorodifluoromethane, propane, nitrogen and the like.

Carriers used in suppository dosage forms that may be used in the invention include a variety of bases such as emulsifying bases or water-soluble-bases, cocoa butter, carbowaxes, polyalkylene glycols (including polyethylene glycols) and triglycerides.

Pharmaceutically acceptable carriers that may be used in the invention also include a wide variety of delivery agents commonly used in formulations, such as polysaccharides, polylysines, polyethyleneimines, liposomes and liposome complexes, phospholipids (such as phosphatidylcholine, phosphatidylserine, phosphatidylethanolamine, phosphatidylinositol, sphingomyelin), lipid vesicles and choline.

As used herein, the term “liquid pharmaceutical formulation” means a liquid composition comprising a pharmaceutically active substance and at least one pharmaceutically acceptable carrier.

As used herein, “integrity” means the chemical or physical integrity, i.e. the degree to which the chemical or physical structure of the measured substance (i.e., either the pharmaceutically active substance or the material) is modified by exposure to the material, resulting in loss of drug or drug product, or degradation of the drug or drug product.

Exemplary changes that may occur for the pharmaceutically active substance include surface adsorption or absorption, aggregation, covalent or ionic bonding (or other chemical interactions) with the material, changes in molecular arrangement, modification of chemical structure (i.e., deamidation or amino acids, oxidation, dimerization), high order aggregates, clipped products (when the active ingredient is an antibody), or changes in the configuration of macromolecules. For pharmaceutically active antibodies, degradation may be measured by the percent of high order aggregates, dimers, monomers and fragments (Fc-Fab or Fab).

Exemplary changes that may occur for the material include surface adsorption or absorption, covalent or ionic bonding (or other chemical interactions) with the pharmaceutically active substance of any excipients, modification of chemical structure (i.e., deamidation or amino acids, oxidation, dimerization), or leaching of materials.

Typical analytical techniques or assays for determining the “integrity” (as defined above) of the pharmaceutically active substances are known to those skilled in the art, and include, but are not limited to, HPLC, including S-E HPLC and R-P HPLC; CEX-HPLS, cIEF; SDS-PAGE; NMR; mass spectrometry; spectroscopy, such as ultra-violet spectroscopy, visible light spectroscopy, near-infra red spectroscopy, fourier transform infrared spectroscopy, Raman spectroscopy, fluorescence spectroscopy, inductively coupled plasma mass spectroscopy (ICP-MS), and Plasmon resonance techniques; dynamic light scattering; and static light scattering. The invention is not intended to be limited to particular techniques or assays for determining the integrity of pharmaceutically active substances. Any technique or assay that measures integrity (as defined above) can be used with the invention.

Typical analytical techniques or assays for determining the “integrity” (as defined above) of the materials are known to those skilled in the art, and include, but are not limited to, R-P HPLC; GC-MS, LC-MS and ICP-MS. The invention is not intended to be limited to particular techniques or assays for determining the integrity of materials. Any technique or assay that measures integrity (as defined above) can be used with the invention.

As used herein, an “integrity readout” is any measure used by those skilled in the art in evaluating the aforementioned techniques or assays. Suitable integrity readouts include any data from chromatography methods, NMR spectra, UV spectra, near infra red spectra and relative retention time (RRT) for HPLC studies.

As used herein, the term “discrete non-reactive vessel” means a container (such as a vial or cylinder) commonly used in pharmaceutical development for conducting assays, such as high throughput assays. Typical discrete non-reactive vessels are arranged in a tray. For example, a 90-well tray may have 90 vials, which are discrete non-reactive vessels within the meaning of the invention. A 96-well tray may have 96 glass cylinders, which are discrete non-reactive vessels within the meaning of the invention.

As used herein, the term “material” includes any substance that could potentially come into contact with the pharmaceutically active substance at any time during the development, manufacture and sale of pharmaceuticals (including research and development, clinical study, storage or sale). The invention is useful in determining compatibility of a wide range of materials that are potential contact surfaces. For example, the invention may be used to determine the compatibility of various solid materials, such as plastics, resins and polymeric structures, rubbers and elastomers, steel and other metals, and glass.

Potential contact surfaces made from plastics and polymers include intravenous bags, intravenous lines, bulk bags, syringes, bottles, tubes or tubing, conical bottles, CPC connectors and stir bars.

Typical intravenous (IV) bags and infusion lines include those made from polyolefins, including ethylene-propylene copolymers, ethylene vinyl alcohol copolymer (EVOH), polyvinyl chloride (PVC), polyethylene, phthalates and ethylene vinyl acetate mono-material (EVAM). Typically, IV bags include PVC bags, with or without DEHP (diethylhexylphthalate) plasticizer; non-plasticizer IV bags, typically comprised of co-polymers of ethylene and propylene (e.g., PAB and EXCEL bags); and polypropylene IV bags.

Suitable bulk bags include those made from ethylene vinyl acetate copolymers, EVOH copolymers and EVAM, and mixtures thereof. Exemplary commercially available bulk bags include those manufactured by STEDIM.

Suitable polymeric syringes include those made from polycarbonate and polypropylene. Typical syringes also include silicone lubricants and latex-free components (such as latex-free plungers).

Exemplary polymeric bottles include those made from polypropylene, polyethylene, polyethylene terephthalate (PET), polystyrene, PVC and mixtures thereof. Exemplary bottles are formed from PET with glycol modifiers.

Suitable polymeric tubing includes tubing made from polyethylene, PET, polystyrene, polypropylene, PVC and mixtures thereof. Polymeric tubing products include silicone, platinum cured or peroxide cured tubes; BioPharm Silicone and BioPharm Plus silicone tubes, PHARMED polysulfone tubes (such as PHARMED High Pressure tubes); TYGON tubes (such as TYGON LFL and TYGON R-3603); PHARMAPURE tubes; and C-FLEX thermoplastic elastomeric tubes.

Exemplary CPC connectors include those made from polysulfone.

Suitable catheters include those from polyurethane and PVC.

Typical polymeric vials include cyclic olefin copolymer (COC) resin vials.

Other polymeric contact surfaces include coatings, such as di-(2-ethylhexyl) phthalate (DEHP), which are used on various components, including catheters, bags, IV bags and lines.

Various elastomers and rubbers are used in the manufacture of potential contact surfaces, including caps, plungers and stoppers. Suitable elastomers and rubbers include chlorobutyl, bromobutyl, isoprene, styrene-butadiene and mixtures thereof. Typical coatings for rubber stoppers and caps include silicone coatings, such as Rhone Poulenc 70041 V30000 and 70047 V30000, Fluoropolymer Resin D, FLUROTEC (West Pharmaceutical Services, Inc.), and OMNIFLEX PLUS coatings (Helvoet Pharma, Inc.; Pennsauken, N.J.).

Exemplary stoppers include HELVOET FM 140/0 13 mm Igloo Lyo Rubber Stopper (Mold V6503), WEST 4432/50 13 mm Igloo Lyo Rubber Stopper (Mold V2-F451W) with FLUROTEC and B2-TR supplied WESTAR RS (West Pharmaceutical Services, Inc.), WEST 4432/50 13 mm Serum Rubber Stopper (Mold WPS S2-F451) with FLUROTEC and B2-40, WEST LyoTec V-50-I 4432/50 Gray stopper with FLUROTEC (on flange) and B2-04, WEST 4405/50 13 mm Slotted Lyo and Latex Free Rubber Stopper (West mold #V-50), HELVOET FM259/0 13 mm Serum Rubber Stopper (mold V9239) with OMNIFLEX PLUS Coating, HELVOET FM457/0 13 mm Rubber Stopper (mold #HPP003), WEST 4432/50 13 mm Serum Rubber Stopper (mold #V-35) with B2-42 and WEST 4023/50 1-3 ml plunger stopper with B2-40, siliconized, HELVOET FM257/2, 1-3 ml plunger stopper, with OMNIFLEX coating, siliconized, WEST 4432/50, 1-3 ml plunger stopper, siliconized, HELVOET FM457/0, 1-3 ml plunger stopper, siliconized, WEST 7025/65 tip cap and HELVOET FM27/0 Tip Cap.

Products and components made from glass include tubes, vials, syringes, bottles and other storage products. Suitable glass components include USP/EP Type I Flint Glass (including untreated NEUTRAPLEX Comar, Inc., Buena, N.J.), USP/EP Type I tubing glass, USP amber glass and borosilicate flint glass. Exemplary glass products include 3 mL round, Flint Glass USP/EP Type I tubing vial, 13 mm; 10 mL, round Flint glass, USP/EP Type I tubing vial; 13 mm aluminum seal finish with blow back 1.5 ml USP/EP Type 1 tubing syringe; siliconized bottle, 3 mL amber USP/EP, 13 mm.

Typical metal products that are product contact surfaces in the pharmaceutical industry include tanks and pipes for use in synthesis, storage tanks, needles and various parts and components used in vials, syringes, and other products. Typical metallic alloys include 316L, 317L, and HASTELLOY C-2000 (Haynes International, Inc., Kokomo, Ind.). HASTELLOY C-2000 is a corrosion resistant alloy that is composed of approximately 50% nickel, and is used in the pharmaceutical industry for bulk storage and transport. Stainless steel and tubing is used used during the manufacture of the bulk and formulation/filling processes. The process tanks used for bulk manufacture are made of 316L and 317L grades stainless steel.

Tungsten is used in the manufacturing of glass vials in the pharmaceutical industry. Vials are usually formed around a tungsten rod. Consequently, a thin layer of oxidized tungsten is often present in completed vials.

The material compatibility screening procedure may also be used with liquid materials that commonly contact pharmaceutically active substances during the research and development of pharmaceuticals, such as silicone oils, peroxides and tungsten liquids.

Unless defined otherwise, all technical and scientific terms used herein have the same meaning as commonly understood by one skilled in the art to which this invention belongs. Although any methods and materials similar or equivalent to those described herein can also be used in the practice or testing of the present invention, the preferred methods and materials are now described. All publications mentioned herein are incorporated herein by reference to disclose and describe the methods and/or materials in connection with which the publications are cited.

As used herein, the singular forms “a”, “and”, and “the” include plural referents unless the context clearly dictates otherwise.

The material compatibility screening procedure of the invention may be performed using a tray (for example, a 90-well tray) having glass vials for holding the materials to be screened. Suitable 90-well trays are commercially available, and are known to those skilled in the art. For example, a commercially available 90-well tray is a polypropylene Wheaton Vial Rack, Cat 868810). The 90-well tray typically uses 3 mL glass vials.

Thereafter, the pharmaceutically active substance, and/or the pharmaceutically acceptable carriers, is added to each tray. The pharmaceutically active substance and carriers are then incubated with a material in each tray.

In one embodiment, the screening procedure is an automated or robotic procedure. Typical robotic methods use a 96-well tray, having a small glass cylinder in each well. Suitable commercially available 1.0 mL cylinders for a 96-well tray are 1.0 mL glass conical vial/Loadr, Catalog 4100-930VL).

The pharmaceutically active substance and/or pharmaceutically acceptable carriers, and materials are dispensed robotically to the cylinder.

Whether prepared manually or robotically, the trays should be prepared under aseptic conditions, for example under a safety hood.

Suitable 96-well robotic trays are commercially available, and are known to those skilled in the art. A suitable commercially available robot for a high-throughput system is a BIOMEK 2000 robot, which can dispense a liquid formulation (containing a pharmaceutically active substance and carriers) into the 96-well glass containers in the tray. Any pharmaceutically active substance as described in this application (with carriers) may be dispensed using the BIOMEK 2000.

The procedure may be performed at ambient temperature in a biosafety cabinet to maintain sterility. Following the dispensing of the pharmaceutically active substance (and/or carrier) into the containers, a sterile cover (mat) may be placed on the containers. The tray containing the glass vials and pharmaceutically active substance and carrier may then be incubated at a range of temperatures. Following incubation, the samples are tested with analytical methods, as described.

For administrative ease, each row of the tray may consist of a group of materials that are used in a specific stage in development, such as in laboratory equipment, safety assessment supplies, processing equipment, drug substance and drug product equipment, and clinical supplies.

The surface area/volume ratio (SA/V) is calculated for each material in a vial. The SA/V may be designed to reflect a set of conditions that is expected to produce a larger impact on the drug loss and degradation values than would more typical conditions. Typical SA/V values for samples of the plurality of materials have a surface area between 1.0 cm²/mL and 10.0 cm²/mL (i.e., from 1.0 cm² material/mL pharmaceutically active substance and carrier, to 10.0 cm²/mL pharmaceutically active substance and carrier). For non-sterile materials, following placement into glass vials, the trays may be placed in autoclave bags and sterilized by autoclaving. The trays may then be removed under a biosafety cabinet, followed by dispensing the liquid formulation into the vials. Materials that are obtained sterilized may be placed directly into pre-sterilized glass vials.

All vials should be stoppered with an identical stopper, e.g. FluoroTec® stoppers, followed by capping.

For vaccines, therapeutic proteins, peptides, and RNAi, one tray may be stored at a predetermined temperature (such as 25° C.) and the other tray may be stored at a control temperature (2-8° C.) as a control for a certain time period (e.g., two weeks). Alternatively, if materials are limited, two control vials without materials may be stored at a predetermined temperature (2-8° C.) and the control tray will not be used. Incubation at 25° C. may be performed to represent storage of the materials and molecules at ambient temperature. Incubation may also enhance the release of leachables from the materials.

Samples may be tested to detect interactions following the first two weeks of incubation at 25° C. with the control samples at a control temperature (e.g., 2-8° C.). Exemplary tests for the degradation assay embodiment include concentration, particle size, aggregation, and fragmentation of the pharmaceutically active substance. Following the initial two week incubation, the 25° C. tray may be transferred to a second temperature (for example 37° C.) in an incubator and incubated for an additional two weeks. The control tray may remain at the control temperature (2-8° C.). Testing may be performed again after the two week incubation at the second temperature (37° C.).

For small molecule formulations, a control sample will be stored at a predetermined temperature (e.g., 5° C. or −20° C.), depending on stability, and trays may be incubated at two predetermined temperatures (e.g., 25 and 40° C.). Samples may be tested at two time points (such as two and four weeks, or four and twelve weeks).

In another embodiment, the “freeze:thaw” embodiment, the tray may be frozen with materials. Samples may be tested to detect interactions following the first two weeks of incubation at a freezing temperature of −70° C. with the control samples at a control temperature (e.g., −1° C.). In another example, samples may be tested to detect interactions following the first two weeks of incubation at a freezing temperature of −70° C. with the control samples at a “thaw” temperature (e.g., 20° C. or 25° C.).

Exemplary tests for the degradation assay embodiment include concentration, particle size, aggregation, and fragmentation of the pharmaceutically active substance.

Following the initial two week incubation, the 25° C. tray may be transferred to a second temperature (for example 37° C.) in an incubator and incubated for an additional two weeks. The control tray may remain at the control temperature (2-8° C.). Testing may be performed again after the two week incubation at the second temperature (37° C.).

A second material compatibility study is recommended using a diluted concentration of the pharmaceutically active substance to assess binding properties to different materials.

The following examples are provided to illustrate the invention and are not to be construed as limiting the scope of the invention in any manner.

### Example 1

### Material Compatibility Screening Procedure Using the Defined Formulation for Safety Assessment

The materials that will be tested using the matrix approach may be arranged in a suitable tray. Table 1 contains a matrix of materials which may be dispensed in a tray, with some of the vials or cylinders left open. Each filled vial or cylinder has a 5 mL volume of a liquid formulation containing a pharmaceutically active substance, and optionally one or more pharmaceutically acceptable carrier. With the exception of the control samples (items 1 and 69), each item represents a vial or cylinder having sample material added to assess compatibility between the pharmaceutically active substance and the material.

TABLE 1

| | | SA/V | SA/V | | |
|---|---|---|---|---|---|
| | | 90-well | 96-well | | USE OF |
| ITEM | SAMPLE MATERIAL | tray | tray | MANUFACTURER | MATERIAL |
| 1 | Control | N/A | N/A | N/A | N/A |
| 2 | Polycarbonate | 6.0 | 3.8 | Boedeker Plastics, Inc. | Container |
| | | | | CR354-00250 | |
| 3 | Polyethylene, LD | 6.0 | 3.8 | Boedeker Plastics, | Container |
| | | | | Inc. CR252-00250 | |
| | | | | Catalog number not | |
| | | | | available | |
| 4 | Polyethylene, HD | 6.0 | 3.8 | Boedeker Plastics, Inc. | Container |
| | | | | CR225-00250 | |
| 5 | Polypropylene | 6.0 | 3.8 | Boedeker Plastics, Inc. | Container/ |
| | | | | CR367-00250 | connector/ |
| | | | | | syringes |
| 6 | Polystyrene | 6.0 | 3.8 | .2 mL pipette, Falcon, Item | Container |
| | | | | 357507 | |
| 7 | Polysulfone | 6.0 | 3.8 | Boedeker Plastics, Inc. | Container/ |
| | | | | CR381-00250 | connector |
| 8 | PTFE Virgin Rod | 6.0 | 3.8 | Boedeker Plastics, Inc. | Container |
| | | | | CR444-00250 | |
| 9 | ACETRON GP Natural | 6.0 | 3.8 | Boedeker Plastics, Inc. | Experimental |
| | Rod | | | CR118-00250-AGP-QUAD | |
| 10 | UHMW Natural Rod | 6.0 | 3.8 | Boedeker Plastics, Inc. | Experimental |
| | | | | CR466-00250 | |
| 11 | ULTEM 1000 Natural | 6.0 | 3.8 | Boedeker Plastics, Inc. | Experimental |
| | Rod | | | CR478-00250 | |
| 12 | PEEK Virgin Natural | 6.0 | 3.8 | Boedeker Plastics, Inc. | Experimental |
| | Rod | | | CR316-00250 | |
| 13 | Nylon Natural Rod | 6.0 | 3.8 | Boedeker Plastics, Inc. | Experimental |
| | | | | CR294-00250 | |
| 14 | PETG | 5.8 | 4.8 | Nalgene Cat 2019-1000 | Container |
| 15 | KYNAR Natural | 6.0 | 3.8 | Boedeker Plastics, Inc. | Experimental |
| | | | | CR248-00250 | |
| 16 | PVC, DEHP Tubing | 4.3 | 5.4 | Surflo Terumo 25 G ½ | Catheters |
| | | | | #367252 | |
| 17 | Polyurethane, non-PVC | 4.3 | 5.4 | CliniCath, Midline, 21-2987- | Catheter |
| | Tubing | | | 24 | |
| 18 | Ethylene/propylene | N/A | N/A | National Scientific | Cryovial seal |
| | o-ring | (float in | (float in | BC16NA-PS | |
| | | solution) | solution) | | |
| 19 | BD Syringe Plunger | 9.0 | 7.5 | Becton Dickinson/#309602 | Plunger in |
| | | | | | syringe |
| 20 | Acrylic | 6.0 | 3.8 | Boedeker Plastics, Inc. | Experimental |
| | | | | R140-00250 | |
| 21 | PVC | 6.0 | 3.8 | Boedeker Plastics, Inc. | Experimental |
| | | | | R393-00250 | |
| 22 | Silicone, platinum- | 4.0 | 5.0 | Masterflex #96410-16 | Tubing- |
| | cured | | | | Form/Fill |
| 23 | BIOPHARM silicone | 4.0 | 5.0 | Masterflex #96420-16 | Tubing- |
| | | | | | Form/Fill |
| 24 | BIOPHARM plus | 4.0 | 5.0 | Masterflex #96440-16 | Tubing- |
| | silicone | | | | Form/Fill |
| 25 | PHARMED | 4.0 | 5.0 | Masterflex #06485-16 | Tubing- |
| | | | | | Form/Fill |
| 26 | PHARMAPURE | 4.0 | 5.0 | Masterflex #06435-16 | Tubing- |
| | | | | | Form/Fill |
| 27 | C-FLEX, clear | 4.0 | 5.0 | Consolidated Polymer | Tubing- |
| | | | | #06422-04 | Form/Fill |
| 28 | C-FLEX, white | 4.0 | 5.0 | Masterflex #06424-16 | Tubing- |
| | | | | | Form/Fill |
| 29 | ADVANTAFLEX | 4.0 | 5.0 | Advanta Pure | Tubing- |
| | | | | #A7500077-50 | Form/Fill |
| 30 | 316L stainless steel | 6.0 | 3.8 | Bosio Metal Specialties/ | Tanks, |
| | (passivated) | | | 316L Stainless | process |
| | | | | | piping |
| 31 | 316L stainless steel | 6.0 | 3.8 | Bosio Metal Specialties/ | Tanks, |
| | (clean) | | | 316L Stainless | process |
| | | | | | piping |
| 32 | 317L stainless steel | 6.0 | 3.8 | Bosio Metal Specialties/ | Bulk storage |
| | (passivated) | | | 317L Stainless | |
| 33 | 317L stainless steel | 6.0 | 3.8 | Bosio Metal Specialties/ | Bulk storage |
| | (clean) | | | 317L Stainless | |
| 34 | HASTELLOY C-2000 | 6.0 | 4.8 | Haynes International, Inc./ | Bulk storage |
| | (passivated) | | | C-2000 | |
| 35 | HASTELLOY C-2000 | 6.0 | 4.8 | Haynes International, Inc./ | Bulk storage |
| | (clean) | | | C-2000 | |
| 36 | HASTELLOY C-22 | 6.0 | 4.8 | Haynes International, Inc./ | Bulk Storage |
| | (passivated) | | | C-2000 | |
| 37 | Tungsten | N/A | N/A | Sigma Aldrich | |
| | | Liquid | | | |
| | | sample | | | |
| 38 | MP35N | 6.0 | 4.8 | Bergen Industrial | Metal, |
| | | | | | Nickel- |
| | | | | | Cobalt Alloy |
| 39 | 445M2 | 6.0 | 4.8 | Austral Wright | Metal, 316L |
| | | | | | alternative, |
| | | | | | more chromium |
| 40 | PVDF, DURAPORE | 2.6 | 3.3 | Millipore #GVWP01300 | Filters |
| 41 | Cellulose acetate | 2.6 | 3.3 | Millipore #GSWP01300 | Filters |
| 42 | Stedim 71 | 4.0 | 5.0 | Stedim, #FBP05M01 | Container |
| 43 | Stedim 40 | 4.0 | 5.0 | Stedim, #SDI1L40 | Container |
| 44 | HYCLONE | 4.0 | 5.0 | Hyclone #SH30657.11 | Container |
| 45 | PUREFLEX LDPE | 4.0 | 5.0 | NovAseptic | Container |
| 46 | Stopper | 4.8 | 6.0 | Helvoet | 13 mm Igloo |
| | | | | FM 140/0 | Lyo Stopper |
| 47 | Stopper | 4.8 | 6.0 | West Pharmaceuticals | 13 mm Igloo |
| | | | | 4432/50 | Lyo Stopper |
| | | | | | w FluroTec |
| | | | | | and B2-TR |
| 48 | Stopper | 4.8 | 6.0 | West Pharmaceuticals | 13 mm |
| | | | | 4405/50 | Slotted Lyo, |
| | | | | | latex free |
| | | | | | Stopper |
| 49 | Stopper | 4.8 | 6.0 | Helvoet | 13 mm |
| | | | | FM 259/0 | Serum |
| | | | | | Stopper w |
| | | | | | Omniflex |
| | | | | | Plus |
| 50 | Stopper | 4.8 | 6.0 | Helvoet | 13 mm |
| | | | | FM 457/0 | Stopper |
| 51 | Stopper | 4.8 | 6.0 | West Pharmaceuticals | 13 mm |
| | | | | 4432/50 | Stopper w |
| | | | | | B2-42 |
| 52 | Stopper | 4.8 | 6.0 | West Pharmaceuticals | 13 mm |
| | | | | 4432/50 | Stopper w |
| | | | | | FluroTec and |
| | | | | | B2-40 |
| 53 | Stopper | 4.8 | 6.0 | Becton Dickinson | 1-3 mL |
| | | | | Helvoet FM257/2 | siliconized |
| | | | | | plunger |
| | | | | | stopper w |
| | | | | | Omniflex |
| 54 | Stopper | 4.8 | 6.0 | Becton Dickinson | 1-3 mL |
| | | | | West 4023/50 | plunger |
| | | | | | stopper w |
| | | | | | B2-40 |
| 55 | Stopper | 4.8 | 6.0 | Becton Dickinson | 1-3 mL |
| | | | | Helvoet FM457/0 | siliconized |
| | | | | | plunger |
| | | | | | stopper |
| 56 | Amber Vial | 4.6 | N/A (vial does not | #50185, Kimble Glass | Vial |
| | | | fit in the 96-well | | |
| | | | matrix) | | |
| 57 | COC Resin Vial | 4.6 | N/A(vial does not | Daikyo Saiko, #2A13 | Vial |
| | | | fit in the 96-well | | |
| | | | matrix) | | |
| 58 | OTSUKA 250 Ml | 4.0 | 5.0 | Otsuka | IV Bag |
| 59 | Non-PVC Opaque IV | 4.0 | 5.0 | B. Braun (PAB Container)/ | IV Bag |
| | bag, saline | | | # S8004-5264 | |
| 60 | Non-PVC Clear IV bag, | 4.0 | 5.0 | B. Braun (EXCEL | IV Bag |
| | saline | | | Container)/# L8001 | |
| 61 | PVC, DEHP, saline | 4.0 | 5.0 | Hospira (VisIV)/#2B132 | IV Bag |
| 62 | PVC, DEHP, saline | 4.0 | 5.0 | Baxter (Viaflex)/#2B132 | IV Bag |
| 63 | VITULIA (isotonico) | 4.0 | 5.0 | ERN (Spain)/999789.2 | IV Bag |
| 64 | DEHP-free PVC | 3.0 | 3.7 | B. Braun, V1390 Fat | Infusion Line |
| | infusion line | | | Emulsion IV Set | |
| 65 | PVC, BAXTER | 3.0 | 3.7 | Baxter, Solution Set, | Infusion Line |
| | infusion line | | | 2C5493s | |
| 66 | BAXTER drip chamber | 4.0 | 5.0 | Baxter, Solution Set, | Drip |
| | | | | 2C5493s | Chamber |
| 67 | DEHP-free PVC drip | 4.0 | 5.0 | B. Braun, V1390 Fat | Drip |
| | chamber | | | Emulsion IV Set | Chamber |
| 68 | Orange Polyethylene- | 4.3 | 5.4 | Hospira (Primary I.V. | Infusion Line |
| | lined IV Line | | | Plumset) 11879-12 | |
| 69 | Control | N/A | N/A | | |

SA/V: surface area of solid material (cm²)/volume of pharmaceutically active substance and carrier (mL) for the 90-well tray (3 mL vial) or 96-well tray (1 mL glass cylinder).

### Stability Testing Schedule

Time zero sample will be taken prior to storage of the trays at the control and accelerated stability temperatures. Following incubation, samples will be taken after two weeks and four weeks. The stability time and incubation temperatures may be modified following the initial stability studies to determine the optimum parameters for evaluating material compatibility.

The following describes the preparation and surface area (SA) to volume (V) ratios for the wells of the materials compatibility screening procedure. The goal is to ensure that materials of similar composition are screened using the same or similar SA/V ratios. As shown in Table 1, not all materials in the example study have the same SA/V ratios.

### 90-Well Tray Format, Preparation of Materials and Calculation of Surface Area/Volume Ratios

The following describes the surface area (SA) to volume (V) ratios for the materials compatibility screening procedure using a 90-well tray with 3 mL glass vials. The goal is to ensure that all materials of similar composition are screened using the same SA/V ratios. However, not all materials in the study have the same SA/V ratios.

Items 2-13 and 15, 20, 21 (plastic/polymer cylinders)

### Preparation

Plastics/polymers are provided by Boedeker Plastics, Inc. as cylinders with a diameter of 6.35 mm (0.25 inches) and a length of 6 mm. The cylinders are prepared by Boedeker Plastics from standard 0.25 inch diameter rod material and cut into 6 mm lengths. Two cylinders are placed upright in each glass vial. Rinse materials in USP water prior to placement in the glass vials.

### Surface Area

Cylinder top (no contact with solution)
Cylinder side: 2πrh=2(3.14)(3.2 mm)(6.0 mm)=1.2 cm²
Cylinder bottom: πr²=(3.14)(3.2 mm)²=32 mm²=0.32 cm²
Total Surface area=1.52 cm²×2 pieces=3.0 cm²
Volume of test material=0.5 mL
Surface Area: Volume=3.0 cm²/0.5 mL=6.0 cm²/mL

### Item 14

### Preparation

1) In a biosafety cabinet, using a scalpel, cut a square 6.0 mm×6.0 mm. Be sure to obtain a piece of material that does not have ink or a label from the container.
2) Place material at the bottom of a pre-sterilized vial

### Surface Area

Faces of sample: 6.0 mm×6.0 mm=36 mm²×2 sides=72.0 mm²
Edges of sample: 6 mm×1 mm×4 edges=24 mm²
Total surface area: 72 mm²+24 mm²=96 mm²×1 cm/10 mm×1 cm/10 mm=0.96 cm²
Surface Area: Volume=0.96 cm²/0.5 mL×3 samples=5.76 cm²/mL=5.8 cm²/mL
Item 15 (same as items 2-13)
Items 16-17 (catheters/infusion lines)
1) Using a 15 cm ruler, place catheter along the edge
2) Cut through catheter at 6 mm intervals using a retractable knife. Ensure the blade is new and clean.
3) Place 3 pieces of tubing upright in a 3 mL glass vial

### Surface Area

### Length=6 mm

### Diameter=2 mm

2πrh (outside cylinder)=2(3.14)(1 mm)(6 mm)=0.38 cm²
2πrh (inside cylinder)=2(3.14)(0.9 mm)(6 mm)=0.34 cm²
Total Surface area=0.72 cm²×3 pieces=2.16 cm²
Volume of test material=0.5 mL
Surface Area: Volume=2.16 cm²/0.5 mL=4.3 cm²/mL
Item 18 (o-ring)
1) Remove the O-rings from the top of the vials using an 18 G1″ needle.
2) Remove a total of 3 O-rings

3) Cut O-rings in ½ using a scissors.

The surface area was not calculated because a minimal amount of the o-ring surface contacts the solution (floats). The o-ring is also not a direct product-contact surface, but is part of the cryovial.

Item 19 (plunger)
1) Remove plunger from 1 mL syringe
2) Remove rubber insert by gently pulling
3) Repeat with 2 additional syringes (total of 3 plungers)

### Surface Area

### Length: 7 mm

### Diameter: 5 mm

Cylinder top and bottom: 2πr²=(2)(3.14)(2.5 mm)²=39.26 mm²=0.39 cm²
Cylinder side: 2πrh=2(3.14)(2.5 mm)(7.0 mm)=1.1 cm² cm²
Total Surface area=1.49 cm²×2 pieces=4.5 cm²
Volume of test material=0.4 mL
Surface Area: Volume=4.5 cm²/0.4 mL=7.45 cm²/mL=7.5 cm²/mL
Items 20, 21—(same as items 2-13)

### Items 22-29 (Tubing)

### Preparation

Different types of tubing were obtained from Cole Parmer and Fisher Scientific. All tubing sizes used are 0.25 inch (6.35 mm) outer diameter and 0.125 inch (3.2 mm) inner diameter.
1) Using a 15 cm ruler, place tubing along the edge
2) Cut through tubing at 6 mm intervals using a retractable knife. Ensure the blade is new and clean.
3) Place 3 pieces of tubing upright in a 3 mL glass vial, one at a time (same procedure as was performed with the plastic/polymers). Because the tubing can change positions while in the vial, use an 18 G×1″ needle to position the tubing in the vial.

### Surface Area

Cylinder top (no contact with solution)
Cylinder side (outside)=2πrh=2(3.14)(3.2 mm)(6 mm)=1.2 cm²
Cylinder (inside)=2πrh=2(3.14)(1.6 mm)(6 mm)=60 mm²=0.60 cm²
Cylinder (bottom)=πr² (outside)−πr²(inside)=[(3.14)(3.2 mm)²]−[(3.14)(1.6 mm)²]=32.15 mm²−8.03 mm²=24.12 mm²=0.24 cm²
Total surface area=2.0 cm²
Volume of test material=0.4 mL
Surface Area: Volume=2.0 cm²/0.4 mL=5.0 cm²/mL
Items 30-33 (stainless steel cylinders)

### Preparation

Stainless steel pieces are provided by Bosio Metal Specialties, Inc. (316L and 317L stainless steel) and Haynes International, Inc. (Hastelloy C-2000) as cylinders with a diameter of 6.35 mm (0.25 inches) and a length of 6 mm. Two cylinders are placed upright in each glass vial.

### Surface Area

Cylinder top (no contact with solution)
Cylinder side: 2πrh=2(3.14)(3.2 mm)(6.0 mm)=1.2 cm²
Cylinder bottom: πr²=(3.14)(3.2 mm)²=32 mm²=0.32 cm²
Total Surface area=1.52 cm²×2 pieces=3.0 cm²
Volume of test material=0.5 mL
Surface Area: Volume=3.0 cm²/0.5 mL=6.0 cm²/mL
Items 34-36 (cylinders)

### Surface Area

Cylinder top (no contact with solution)
Cylinder side: 2πrh=2(3.14)(1.5 mm)(6.0 mm)=0.565 cm²
Cylinder bottom: πr²=(3.14)(1.5 mm)²=7.06 mm²=0.07 cm²
Total Surface area=0.565 cm²+0.07 cm²=0.635 cm²
Volume of test material=0.4 mL
Surface Area: Volume=0.635 cm²/0.4 mL×3 pieces=4.8 cm²/mL
Item 37—liquid sample (no surface area calculation)
Items 38, 39 (same as 30-33)
Items 40, 41 (filters)

### Preparation

Filters are provided as individual discs, 13 mm in diameter.

### Surface Area

### Diameter=13 mm

Disc=πr²=(3.14)(6.5 mm)²=132.7 mm²=1.32 cm²
Total Surface area=1.32 cm²
Volume of test material=0.5 mL
Surface Area: Volume=1.32 cm²/0.5 mL=2.6 cm²/mL

### Items 42-45

(see section for items 61-63)
Surface Area: Volume=2.0 cm²/0.5 mL=4.0 cm²/mL
Items 46-55 (stoppers)

### Preparation

1) Cut the inside neck piece off (results in a hollow cylinder) using a retractable knife
2) Place 2 cut pieces from each stopper into a 3 mL vial

### Surface Area

Cylinder: 2πrh=2(3.14)(3.2 mm)(6.0 mm)=1.2 cm²
Total Surface area=1.2 cm²×2 pieces=2.4 cm²
Volume of test material=0.5 mL
Surface Area: Volume=2.4 cm²/0.5 mL=4.8 cm²/mL

### Items 56-57

Cylinder side: 2πrh=2(3.14)(7.5 mm)(6.0 mm)=2.8 cm²
Cylinder bottom: πr²=(3.14)(7.5 mm)²=177 mm²=1.77 cm²
Total Surface area=2.8 cm²+1.77 cm²=4.57 cm²
Volume of test material=1.0 mL
Surface Area: Volume=4.57 cm²/1.0 mL=4.6 cm²/mL
Items 58-63 (Same as items 42-45)
Items 64-65 (same as items 16-17)

### Items 66-67

### Preparation

1) In a biosafety cabinet, using a scissors treated with 70% ethanol, cut a piece of material 1.0 cm×1.0 cm. Be sure to obtain a piece of material that does not have ink or a label from the bag.
2) Place material at the bottom of a pre-sterilized vial

### Surface Area

1.0 cm×1.0 cm=1.0 cm²×2 sides=2.0 cm²
Surface Area: Volume=2.0 cm²/0.5 mL=4.0 cm²/mL
Item 68 (same as items 16-17)

### 96-Well Tray Format, Preparation of Materials and Calculation of Surface Area/Volume Ratios

The following describes the surface area (SA) to volume (V) ratios for the materials compatibility screening procedure using a 96-well tray. The goal is to ensure that all materials of similar composition are screened using the same SA/V ratios. However, not all materials in the study have the same SA/V ratios.
Items 2-13 and 15, 20, 21 (plastic/polymer cylinders)

### Preparation

Plastics/polymers are provided by Boedeker Plastics, Inc. as cylinders with a diameter of 6.35 mm (0.25 inches) and a length of 6 mm. The cylinders are prepared by Boedeker Plastics from standard 0.25 inch diameter rod material and cut into 6 mm lengths. One cylinder is placed upright in each glass vial. Rinse materials in USP water prior to placement in the glass vials.

### Surface Area

Cylinder top (no contact with solution)
Cylinder side: 2πrh=2(3.14)(3.2 mm)(6.0 mm)=1.2 cm²
Cylinder bottom: πr²=(3.14)(3.2 mm)²=32 mm²=0.32 cm²
Total Surface area=1.52 cm²
Volume of test material=0.4 mL
Surface Area: Volume=1.52 cm²/0.4 mL=3.8 cm²/mL

### Item 14

### Preparation

1) In a biosafety cabinet, using a scalpel, cut a square 6.0 mm×6.0 mm. Be sure to obtain a piece of material that does not have ink or a label from the container.
2) Place material at the bottom of a pre-sterilized vial

### Surface Area

Faces of sample: 6.0 mm×6.0 mm=36 mm²×2 sides=72.0 mm²
Edges of sample: 6 mm×1 mm×4 edges=24 mm²
Total surface area: 72 mm²+24 mm²=96 mm²×1 cm/10 mm×1 cm/10 mm=0.96 cm²
Surface Area: Volume=0.96 cm²/0.4 mL×2 pieces=4.8 cm²/mL
Item 15 (see items 2-13)
Items 16-17 (catheters/infusion lines)
1) Using a 15 cm ruler, place catheter along the edge
2) Cut through catheter at 6 mm intervals using a retractable knife. Ensure the blade is new and clean.
3) Place 3 pieces of tubing upright in a 3 mL glass vial

### Surface Area

### Length=6 mm

### Diameter=2 mm

2πrh (outside cylinder)=2(3.14)(1 mm)(6 mm)=0.38 cm²
2πrh (inside cylinder)=2(3.14)(0.9 mm)(6 mm)=0.34 cm²
Total Surface area=0.72 cm²×3 pieces=2.16 cm²
Volume of test material=0.4 mL
Surface Area: Volume=2.16 cm²/0.4 mL=5.4 cm²/mL
Item 18 (o-ring)
1) Remove the O-rings from the top of the vials using an 18 G 1″ needle.
2) Remove a total of 3 O-rings
3) Cut O-rings in ½ using a scissors.
The surface area was not calculated because a minimal amount of the o-ring surface contacts the solution (floats). The o-ring is also not a direct product-contact surface, but is part of the cryovial.
Item 19 (plunger)
1) Remove plunger from 1 mL syringe
2) Remove rubber insert by gently pulling
3) Repeat with 2 additional syringes (total of 3 plungers)

### Surface Area

### Length: 7 mm

### Diameter: 5 mm

Cylinder top and bottom: 2πr²=(2)(3.14)(2.5 mm)²=39.26 mm²=0.39 cm²
Cylinder side: 2πrh=2(3.14)(2.5 mm)(7.0 mm)=1.1 cm² cm²
Total Surface area=1.49 cm²×3 pieces=4.5 cm²
Volume of test material=0.4 mL
Surface Area: Volume=4.5 cm²/0.4 mL=1.25 cm²/mL
Items 20, 21—(same as items 2-13)

### Items 22-29 (Tubing)

### Preparation

Different types of tubing were obtained from Cole Parmer and Fisher Scientific. All tubing sizes used are 0.25 inch (6.35 mm) outer diameter and 0.125 inch (3.2 mm) inner diameter.
1) Using a 15 cm ruler, place tubing along the edge
2) Cut through tubing at 6 mm intervals using a retractable knife. Ensure the blade is new and clean.
3) Place 3 pieces of tubing upright in a 3 mL glass vial, one at a time (same procedure as was performed with the plastic/polymers). Because the tubing can change positions while in the vial, use an 18 G×1″ needle to position the tubing in the vial.

### Surface Area

Cylinder top (no contact with solution)
Cylinder side (outside)=2πrh=2(3.14)(3.2 mm)(6 mm)=1.2 cm²
Cylinder (inside)=2πrh=2(3.14)(1.6 mm)(6 mm)=60 mm²=0.60 cm²
Cylinder (bottom)=πr² (outside)−πr²(inside)=[(3.14)(3.2 mm)²]−[(3.14)(1.6 mm)²]=32.15 mm²−8.03 mm²=24.12 mm²=0.24 cm²
Total surface area=2.0 cm²
Volume of test material=0.4 mL
Surface Area: Volume=2.0 cm²/0.4 mL=5.0 cm²/mL
Items 30-33 (stainless steel cylinders)

### Preparation

Stainless steel pieces are provided by Bosio Metal Specialties, Inc. (316L and 317L stainless steel) and Haynes International, Inc. (Hastelloy C-2000) as cylinders with a diameter of 6.35 mm (0.25 inches) and a length of 6 mm. Two cylinders are placed upright in each glass vial.

### Surface Area

Cylinder top (no contact with solution)
Cylinder side: 2πrh=2(3.14)(3.2 mm)(6.0 mm)=1.2 cm²
Cylinder bottom: πr²=(3.14)(3.2 mm)²=32 mm²=0.32 cm²
Total Surface area=1.52 cm²×2 pieces=3.0 cm²
Volume of test material=0.4 mL
Surface Area: Volume=3.0 cm²/0.4 mL=7.5 cm²/mL

### Items 34-36 (Tubing)

Item 37—liquid sample (no surface area calculation)
Items 38-39 (same as 30-33)
Items 40, 41 (filters)

### Preparation

Filters are provided as individual discs, 13 mm in diameter.

### Surface Area

### Diameter=13 mm

Disc=πr²=(3.14)(6.5 mm)²=132.7 mm²=1.32 cm²
Total Surface area=1.32 cm²
Volume of test material=0.4 mL
Surface Area: Volume=1.32 cm²/0.4 mL=3.3 cm²/mL

### Items 42-45

(see section for items 61-63)
Surface Area: Volume=2.0 cm²/0.4 mL=5.0 cm²/mL
Items 46-55 (stoppers)

### Preparation

1) Cut the inside neck piece off (results in a hollow cylinder) using a retractable knife
2) Place 2 cut pieces from each stopper into a 3 mL vial

### Surface Area

Cylinder: 2πrh=2(3.14)(3.2 mm)(6.0 mm)=1.2 cm²
Total Surface area=1.2 cm²×2 pieces=2.4 cm²
Volume of test material=0.4 mL
Surface Area: Volume=2.4 cm²/0.4 mL=6.0 cm²/mL

### Items 56-57—N/A

Items 58-63 (same as items 42-45)
Items 64-65 (same as items 16-17)

### Items 66-67

### Preparation

1) In a biosafety cabinet, using a scissors treated with 70% ethanol, cut a piece of material 1.0 cm×1.0 cm. Be sure to obtain a piece of material that does not have ink or a label from the bag.
2) Place material at the bottom of a pre-sterilized vial

### Surface Area

1.0 cm×1.0 cm=1.0 cm²×2 sides=2.0 cm²
Surface Area: Volume=2.0 cm²/0.4 mL=5.0 cm²/mL
Item 68 (same as items 16-17)

### Example 2

### Use of Matrix for Testing the Material Compatibility of a Therapeutic Monoclonal Antibody (Degradation Assay)

A multi-well tray similar to the matrix described in Example 1 was used to assess the material compatibility of a therapeutic antibody drug candidate. The antibody was incubated with the materials for two weeks at 25° C., and the trays were tested for SEC-HPLC.

Observation: An increase in high-order aggregates (HOA) and dimers of the monoclonal antibody was observed with the ethylene-propylene O-ring when compared to the control. A similar increase in HOAs and dimers was not observed with the other materials tested. Partial results are provided in Table 2 below:

TABLE 2

| | % High- | | | | |
|---|---|---|---|---|---|
| | Order | % | % | % | % |
| Sample Name | Aggregates | Dimer | Monomer | Fc-Fab | Fab |
| Control | 0.02 | 1.44 | 97.88 | 0.44 | 0.22 |
| Polycarbonate | 0.06 | 1.71 | 97.20 | 0.68 | 0.34 |
| Polyethylene, HD | 0.05 | 1.61 | 97.45 | 0.60 | 0.30 |
| Polypropylene | 0.04 | 1.62 | 97.46 | 0.59 | 0.30 |
| Polysulfone | 0.02 | 1.69 | 97.29 | 0.66 | 0.33 |
| PTFE virgin rod | 0.03 | 1.66 | 97.32 | 0.66 | 0.33 |
| PVC, DEHP Tubing | 0.02 | 1.52 | 97.76 | 0.46 | 0.23 |
| Ethylene-Propylene | 0.18 | 5.35 | 93.87 | 0.40 | 0.20 |
| O-ring | | | | | |

### Example 3

### Use of Matrix for Testing the Material Compatibility of a Therapeutic Monoclonal Antibody (Degradation Assay)

A multi-well tray similar to the matrix described in Example 1 was used to assess the material compatibility of a therapeutic protein drug candidate. The protein was incubated with the materials for three weeks at 30° C., and the trays were tested for SEC-HPLC.

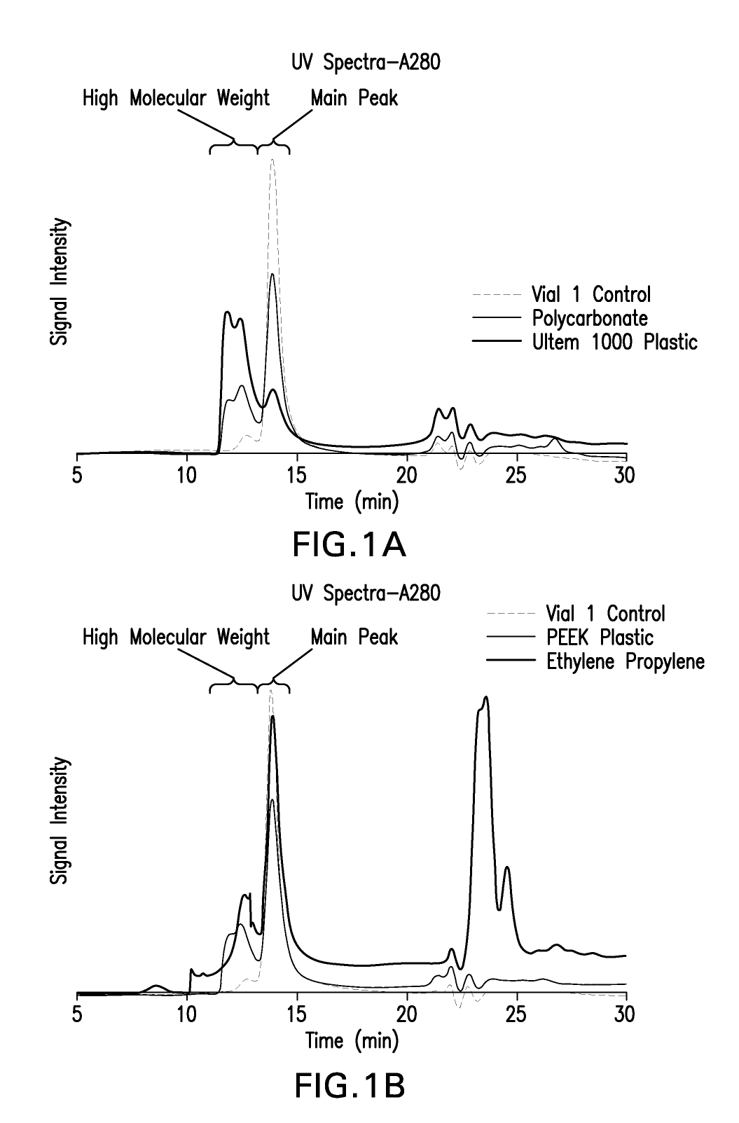

Observation: An increase in aggregates of a therapeutic protein was observed with polycarbonate, Ultem 1000 plastic, PEEK plastic, and an ethylene-propylene o-ring when compared to the control. The results are depicted in chromatogram FIGS. 1A and 1B. FIG. 1A is a chromatogram with ultraviolet detection of a therapeutically active protein as a control, as incubated with polycarbonate material, and as incubated with ULTEM 1000 plastic material (polyetherimide). FIG. 1B is a chromatogram with ultraviolet detection of the same therapeutic protein active ingredient as a control, as incubated with PEEK material, and as incubated with an ethylene propylene material.

### Example 4

### Use of Matrix for Testing the Material Compatibility of a Small Molecule Drug Candidate (Degradation Assay)

A multi-well tray similar to the matrix described in Example 1 was used to assess the material compatibility of a small molecule drug candidate. The drug candidate was incubated with the materials for 48 hours at 25° C., and the trays were tested for HPLC-UV.

Observation: An increase in peaks at 0.23 RRT, 0.75 RRT and active of the small molecule drug candidate was observed with the Polyethylene LD when compared to the control. However, a decrease in peaks at 0.23 relative retention time (RRT), 0.75 RRT and active of the small molecule drug candidate was observed with the Deltec 21-7036 CADD when compared to the control. Deltec 21-7036 CADD is a commercially available filter (SIMS Deltec, Inc., St. Paul, Minn.) made from PVC tubing having a tris-octyl-trimellitate plasticizer.

Partial results are provided in Table 3 below:

TABLE 3

| | 0.23 RRT | 0.75 RRT | Active Ingredient |
|---|---|---|---|
| Sample Name | (Area counts) | (Area counts) | (Area counts) |
| Control | 6.4 | 32.3 | 1405.8 |
| Polyethylene, LD | 10.3 | 32.9 | 1430.7 |
| Deltec 21-7036 | 4.0 | 21.0 | 1314.0 |
| CADD | | | |

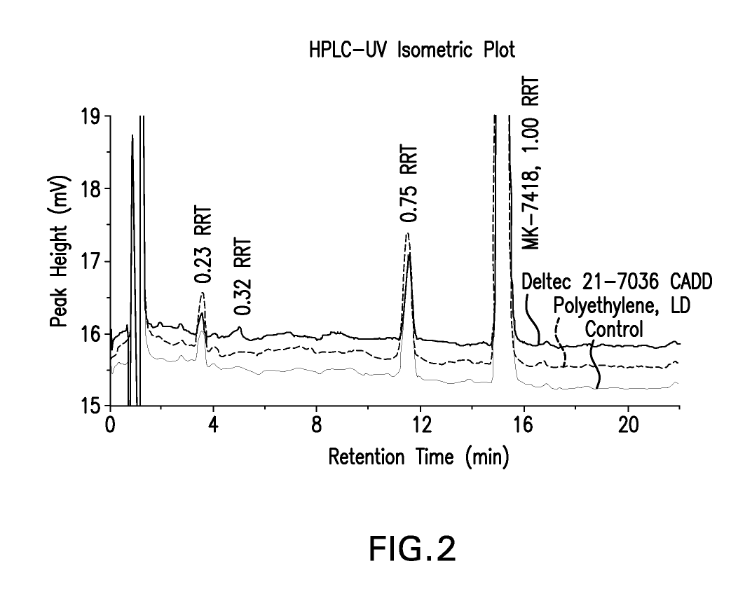

FIG. 2 depicts the chromatogram with ultraviolet detection of the small molecule active ingredient as a control, as incubated with low density polyethylene, and as incubated with the Deltec 21-7036 CADD material.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. It is intended, therefore, that the invention be defined by the scope of the claims that follow and that such claims be interpreted as broadly as is reasonable.

What is claimed is:

1. A method for screening compatibility of a pharmaceutically active substance with a plurality of materials, comprising the steps of:
(a) providing at least one pharmaceutically active substance and optionally at least one pharmaceutically acceptable carrier;
(b) providing a plurality of materials, wherein each of the materials is present in a discrete non-reactive vessel;
(c) incubating the pharmaceutically active substance and the optional pharmaceutically acceptable carrier with each of the plurality of materials in the non-reactive vessels;
(d) measuring integrity of the pharmaceutically active substance in each of the non-reactive vessels to obtain a first set of integrity readouts;
(e) comparing the first set of integrity readouts with one or more control integrity readouts.

2. The method of claim 1, wherein the control integrity readout is generated by the steps of:
(f) incubating the pharmaceutically active substance and optionally the pharmaceutically acceptable carrier in a control non-reactive vessel; and
(g) measuring the integrity of the pharmaceutically active substance in the control non-reactive vessel to obtain a control integrity readout.

3. The method of claim 1, wherein the integrity is determined by an analytical method selected from the group consisting of high performance liquid chromatography, cation exchange liquid chromatography, capillary isoelectric focusing, sodium dodecyl sulfate polyacrylamide gel electrophoresis, nuclear magnetic resonance, mass spectrometry, spectroscopic techniques, dynamic light scattering and static light scattering.

4. The method of claim 1, wherein the pharmaceutically active substance is selected from the group consisting of proteins, vaccines, RNAi, peptides, and small molecules.

5. The method of claim 1, wherein the incubation of step (c) is conducted at a temperature of from 15° C. to 50° C.

6. The method of claims 2, wherein the incubation of step (f) is conducted at a temperature lower than that of step (c).

7. The method of claim 5, wherein the incubation of step (c) occurs at a temperature of from 2° C. to 8° C.

8. The method of claim 1, wherein the incubation of step (c) is conducted at a temperature from −75° C. to −25° C.

9. The method of claim 1, wherein the incubation of step (c) is for a period of time from 24 hours to six weeks.

10. The method of claim 1, wherein the surface area to volume ratio of the plurality of materials to the pharmaceutically active substance and cancer is from 1.0 cm²/mL to 10.0 cm²/mL.

11. The method of claim 1, wherein the non-reactive vessels are glass cylinders in a 96-well tray.

12. The method of claim 11, which is conducted as a high-throughput robotic assay.

13. A method for screening compatibility of a pharmaceutically active substance or a pharmaceutically acceptable carrier with a plurality of materials, comprising the steps of:
(a) providing at least one pharmaceutically active substance or at least one pharmaceutically acceptable carrier;
(b) providing a plurality of materials, wherein each of the materials is present in a discrete non-reactive vessel;
(c) incubating the pharmaceutically active substance or pharmaceutically acceptable carrier with each of the plurality of materials in the non-reactive vessels;
(d) measuring integrity of the materials in each of the non-reactive vessels to obtain a first set of integrity readouts; and
(e) comparing the first set of integrity readouts with one or more control integrity readouts.

14. The method of claim 13, wherein the control integrity is generated by the steps of:
(f) incubating the pharmaceutically active substance or pharmaceutically acceptable carrier in a control non-reactive vessel; and
(g) measuring the integrity of the pharmaceutically active substance or pharmaceutically acceptable carrier in the control non-reactive vessel to obtain a control integrity readout.

15. The method of claim 13, wherein the integrity of the material is determined by an analytical method selected from the group consisting of reverse-phase high performance liquid chromatography gas chromatography-mass spectroscopy, liquid chromatography-mass spectroscopy and inductively coupled plasma mass spectroscopy.

16. The method of claim 13, wherein the pharmaceutically active substance or pharmaceutically acceptable carrier is a liquid pharmaceutical formulation.

17. The method of claim 13, wherein the materials are incubated with one or more pharmaceutically acceptable carriers, but without a pharmaceutically active ingredient.

18. The method of claim 17, which is conducted as a high-throughput robotic assay.
